(19) United States
(12) Patent Application Publication
(10) Pub. No.: US 2025/0183009 A1
(43) Pub. Date: Jun. 5, 2025

(54) METALLIC ARTICLES, SEMICONDUCTOR PROCESSING SYSTEMS HAVING METALLIC ARTICLES, AND METHODS OF MAKING METALLIC ARTICLES

(71) Applicant: ASM IP Holding B.V., Almere (NL)

(72) Inventors: Amin Azimi, Phoenix, AZ (US); Xing Lin, Chandler, AZ (US)

(21) Appl. No.: 18/961,902

(22) Filed: Nov. 27, 2024

Related U.S. Application Data
(60) Provisional application No. 63/605,093, filed on Dec. 1, 2023.

(51) Int. Cl. H01J 37/32; H01J 9/24

(52) U.S. Cl. CPC H01J 37/32495; H01J 9/245; H01J 37/3244; H01J 37/32467; H01J 37/32807; H01J 2237/0213; H01J 2237/335

(57) ABSTRACT

A method of making a metallic article includes forming a workpiece body from a bulk metallic material, forming a metallic oxide layer from the bulk metallic material overlaying the bulk metallic material by exposing the bulk metallic material to ozone (O₃), and depositing a ceramic layer onto the metallic oxide layer. The bulk metallic material includes one of aluminum and nickel, and metallic articles and semiconductor processing systems including metallic articles are also described.

CROSS-REFERENCE TO RELATED APPLICATION(S)

This Application claims the benefit of U.S. Provisional Application 63/605,093 filed on Dec. 1, 2023, the entire contents of which are incorporated herein by reference.

### FIELD OF INVENTION

The present disclosure generally relates to metallic articles, and more particularly to metallic articles having ceramic layers overlaying bulk metallic materials.

### BACKGROUND OF THE DISCLOSURE

Metallic articles are commonly employed in fluid systems such as fluid systems employed to communicate corrosive and/or high temperature fluids in semiconductor processing systems, gas turbine engines, and chemical processing applications. In some applications a metallic article may have a barrier coating operative to separate the fluid conveyed by the fluid system from a bulk metallic material forming the metallic article, for example to prolong the expected service life of the metallic article. The barrier coating may include a metal or a rare-earth metal, as appropriate for the fluid conveyed by the fluid system.

While generally acceptable in terms of separating fluid traversing the fluid system from metallic structures forming the fluid system, ceramic material may be prone to delamination. Since delamination may expose the underlying bulk metallic material to potentially corrosive materials, metallic structures with ceramic barriers commonly undergo scheduled inspection and/or cyclic removal and replacement for refurbishment, increasing cost of ownership of fluid systems employing metallic structures with such barrier materials.

Such systems and methods have generally been acceptable for their intended purpose. However, there remains a need in the art for improved metallic articles, methods, semiconductor processing systems having such metallic articles, and methods of making metallic articles. The present disclosure provides a solution to this need.

### SUMMARY OF THE DISCLOSURE

A method of making a metallic article is provided. The method includes forming a workpiece body from a bulk metallic material, the bulk metallic material including one of aluminum and nickel; forming a metallic oxide layer overlaying the bulk metallic material from the bulk metallic material by exposing the bulk metallic material to ozone (O₃); and depositing a ceramic layer onto the metallic oxide layer.

In addition to one or more of the features described above, or as an alternative, further examples of the method may include that forming the workpiece body include defining a first surface with a circular periphery, defining a second surface separated from the first surface by a thickness, and defining a plurality of flow apertures within the workpiece body fluidly coupling the first surface with the second surface of the workpiece body.

In addition to one or more of the features described above, or as an alternative, further examples of the method may include that forming the metallic oxide layer includes supporting the workpiece body in an ozone chamber; heating the workpiece body to between about 200 degrees Celsius and about 400 degrees Celsius, or between about 200 degrees Celsius and about 350 degrees Celsius, or between about 200 degrees Celsius and about 300 degrees Celsius, or between about 200 degrees Celsius and about 250 degrees Celsius; and exposing the workpiece body to ozone (O₃) gas for between about 15 minutes and about 5 hours, or between about 15 minutes and about 4 hours, or between about 15 minutes and about 3 hours, or between about 15 minutes and about 2 hours.

In addition to one or more of the features described above, or as an alternative, further examples of the method may include wet cleaning the workpiece body prior to forming the metallic oxide layer.

In addition to one or more of the features described above, or as an alternative, further examples of the method may include that substantially none of the metallic oxide layer is formed during the wet cleaning.

In addition to one or more of the features described above, or as an alternative, further examples of the method may include the metallic oxide layer is a second metallic oxide layer, and that that the method further includes forming a first metallic oxide layer on the workpiece body during the wet cleaning, whereby the second metallic oxide layer overlays the first metallic oxide layer following the exposing the bulk metallic material to the ozone (O₃).

In addition to one or more of the features described above, or as an alternative, further examples of the method may include depositing the ceramic layer includes depositing aluminum oxide (Al₂O₃) or yttrium(III) oxide (Y₂O₃) onto the metallic oxide layer.

In addition to one or more of the features described above, or as an alternative, further examples of the method may include indirectly adhering the ceramic layer to the bulk metallic material with the metallic oxide layer, and that exposing the bulk metallic material to the ozone (O₃) prevents forming a metal-to-ceramic bonding barrier transition between the bulk metallic material and the ceramic layer operable to limit adhesion of the ceramic layer to the bulk metallic material.

In addition to one or more of the features described above, or as an alternative, further examples of the method may include fluidly coupling a fluid source to an exhaust source with the metallic article; communicating a corrosive fluid issued by the fluid source to the exhaust source through a preclean process space the metallic article; precleaning a substrate supported fluidly between the metallic article and the exhaust source; supporting the substrate, subsequent to precleaning the substrate, in a deposition process space remote from the preclean process space; and depositing a silicon-containing material layer onto the silicon surface while supported within the deposition process space. The corrosive fluid may include a radical species, and precleaning may remove at least one of interfacial oxygen and interfacial carbon are removed a silicon surface of the substrate.

In addition to one or more of the features described above, or as an alternative, further examples of the method may include, subsequent to depositing the ceramic layer onto the metallic oxide layer overlaying the bulk metallic material, arranging the metallic article within a chamber body of a semiconductor processing system above a substrate support such that the metallic article fluidly couples an inlet port to an outlet port of the chamber body.

In addition to one or more of the features described above, or as an alternative, further examples may include a showerhead metallic article made using the method.

A metallic article is provided. The metallic article includes a workpiece body formed from a bulk metallic material; a metallic oxide layer overlaying the bulk metallic material; and a ceramic layer overlaying the metallic oxide layer, the metallic oxide layer being an oxide formed (or converted) from the bulk metallic material forming the workpiece body.

In addition to one or more of the features described above, or as an alternative, further examples of the metallic article may include that the bulk metallic material includes one of aluminum and nickel.

In addition to one or more of the features described above, or as an alternative, further examples of the metallic article may include that the metallic oxide layer is aluminum oxide (Al₂O₃) or nickel oxide (NiO).

In addition to one or more of the features described above, or as an alternative, further examples of the metallic article may include that the metallic oxide layer has a thickness that is between about 10 nanometers and about 100 nanometers, or between about 20 nanometers and about 80 nanometers, or between about 20 nanometers and about 50 nanometers.

In addition to one or more of the features described above, or as an alternative, further examples of the metallic article may include ceramic layer includes at least one of alumina, aluminum oxide (Al₂O₃) and yttrium(III) oxide (Y₂O₃). The ceramic layer may be formed using a chemical vapor deposition technique or an atomic layer deposition technique.

In addition to one or more of the features described above, or as an alternative, further examples of the metallic article may include that the metallic workpiece is configured to communicate a corrosive fluid received at first surface to a second surface through a thickness of the workpiece body formed by the bulk metallic material.

In addition to one or more of the features described above, or as an alternative, further examples of the metallic article may include the workpiece body defines a showerhead metallic article for a semiconductor processing system.

In addition to one or more of the features described above, or as an alternative, further examples of the metallic article may include that the workpiece body has a first surface with a circular periphery; a second surface separated from the first surface by a thickness; and a plurality of flow apertures fluidly coupling the first surface with the second surface of the workpiece body, the metallic oxide layer extending continuously and without interruption along interior surfaces of the plurality of flow apertures.

In addition to one or more of the features described above, or as an alternative, further examples of the metallic article may include that the plurality of flow apertures have an effective flow area width that is between about 0.25 millimeters and about 4 millimeters, or between about 0.25 millimeters and about 3 millimeters, or between about 0.25 millimeters and about 2 millimeters, or is between about 0.25 millimeters and about 1 millimeter.

A semiconductor processing system is provided. The semiconductor processing system includes a chamber body with an inlet port and an outlet port, a substrate support arranged within an interior of the chamber body, a metallic article as described above seated in the interior of the chamber body and fluidly coupling the inlet port to the outlet port; a corrosive fluid source including a corrosive fluid coupled to the inlet port, and an exhaust source coupled to the outlet port.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a metallic article in accordance with an example of the present disclosure, showing a workpiece body formed from a bulk metallic material with a metallic oxide layer and a ceramic layer overlaying the bulk metallic material;

FIGS. 2-5 are schematic view of a method of making the metallic article of FIG. 1 according to an example of the present disclosure, sequentially showing the metallic oxide being formed using ozone and the ceramic material thereafter being deposited onto the metallic oxide;

FIGS. 6-8 are a process flow diagram of a method of making the metallic article of FIG. 1 according to an example of the present disclosure, showing operations of the method according to an illustrative and non-limiting example of the disclosure;

FIGS. 9 and 10 are schematic views of a showerhead and a semiconductor processing system including the metallic article of FIG. 1, showing flow apertures extending through the workpiece body and a corrosive fluid traversing the flow apertures, respectively; and

FIGS. 11-14 are images of metallic articles undergoing ceramic layer adhesion testing, showing greater ceramic layer adhesion in a metallic article of FIG. 1 relative to a metallic article not having a metallic oxide layer between the bulk metallic material and a ceramic coating.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

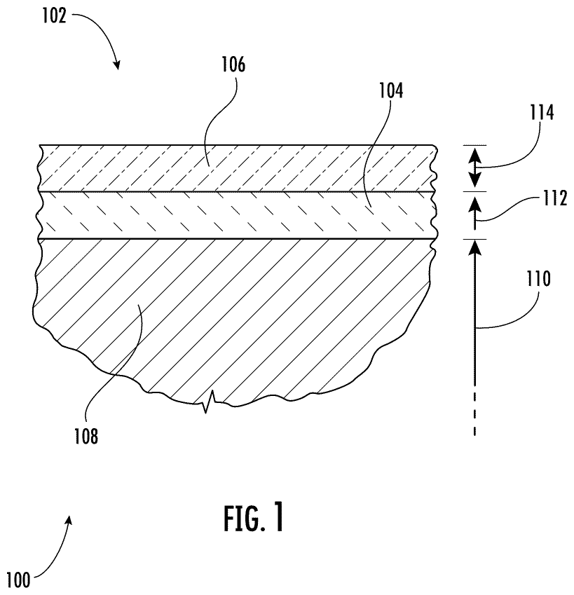

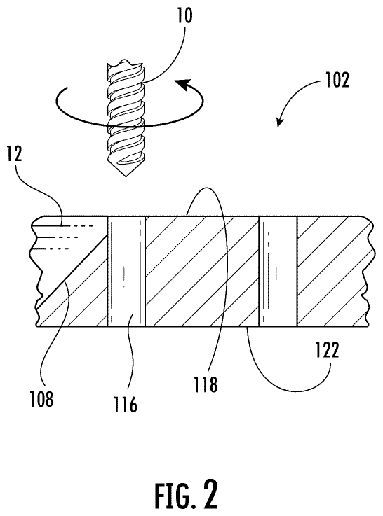

Reference will now be made to the drawings wherein like reference numerals identify similar structural features or aspects of the subject disclosure. For purposes of explanation and illustration, and not limitation, a partial view of an example of a metallic article in accordance with the present disclosure is shown in FIG. 1 and is designated generally by reference character 100. Other examples of metallic articles, semiconductor processing systems including metallic articles, and methods of making metallic articles in accordance with the present disclosure, or aspects thereof, are provided in FIGS. 2-14, as will be described. The metallic articles and methods of making metallic articles of the present disclosure may be used to make showerheads for preclean process modules and material layer deposition process modules, such as preclean modules employed on cluster-type platforms to remotely preclean substrates prior to deposition of silicon-containing material layers using chemical vapor deposition (CVD) and/or atomic layer deposition (ALD) techniques, though the present disclosure is not limited to any particular type of processing nor to semiconductor processing systems in general.

Referring to FIG. 1, a portion of the metallic article 100 is shown. In the illustrated example the metallic article 100 generally includes a workpiece body 102, a metallic oxide layer 104, and a ceramic layer 106. The workpiece body 102 is formed from a bulk metallic material 108 and in this respect may consist of or consist essentially of the bulk metallic material 108. In certain examples of the present disclosure the bulk metallic material 108 may include nickel (e.g., solid nickel (Ni) metal), a nickel-based alloy, or a nickel-containing alloy such as stainless steel. In accordance with certain examples, the bulk metallic material 108 may consist of or consist essentially of nickel (Ni) metal. It is also contemplated that, in accordance with certain examples, the bulk metallic material 108 may include aluminum such as solid aluminum (Al) metal, an aluminum-based alloy, or an aluminum-containing alloy. In this respect the bulk metallic material 108 may consist of or consist essentially of aluminum (Al) metal, an aluminum-based alloy, or an aluminum-containing alloy.

The metallic oxide layer 104 overlays the bulk metallic material 108 and may be formed onto the bulk metallic material 108. In certain examples of the present disclosure the metallic oxide layer may be an oxide formed from the bulk metallic material 108 forming the workpiece body 102, the bulk metallic material 108 contributing metal atoms to the metallic oxide layer 104 during forming of the metallic oxide layer 104. In this respect it is contemplated that the metallic oxide layer 104 may be conformally disposed on the bulk metallic material 108. In further respect, the metallic oxide layer 104 may encapsulate substantially all the bulk metallic material 108. It is contemplated that the metallic oxide layer 104 include (or consist of or consist essentially of) an oxide of the bulk metallic material 108 forming the workpiece body 102. For example, in examples wherein the bulk metallic material 108 is solid nickel, the metallic oxide layer 104 may include (or consist of or consist essentially of) nickel(II) oxide (NiO), though metallic oxide coatings includes including Ni(III) oxide (Ni₂O₃) and mixtures thereof are contemplated within the scope of the present disclosure. In such examples the nickel (Ni) metal contained within the nickel oxide (NiO) may originate from the bulk metallic material 108 forming the workpiece body 102, the nickel oxide (NiO) formed by exposing the workpiece body to ozone (O₃).

In certain examples of the present disclosure the bulk metallic material 108 forming the workpiece body 102 may be solid aluminum (Al) metal, and the metallic oxide layer 104 may include (or consist of or consist essentially of) aluminum oxide (Al₂O₃). The aluminum (Al) constituent in the aluminum oxide (Al₂O₃) in such examples may originate in the solid aluminum (Al) metal forming the workpiece body 102 and/or through a native aluminum oxide (A1₂O₃) coating resident on the workpiece body 102, the aluminum oxide (Al₂O₃) formed by exposing the aluminum (Al) metal (or through a native aluminum oxide (Al₂O₃) layer) to ozone (O₃).

The ceramic layer 106 overlays (e.g., is formed onto) the metallic oxide layer 104 and may be conformally disposed onto the metallic oxide layer 104. The ceramic layer 106 may further encapsulate both the metallic oxide layer 104 and the underlying the bulk metallic material 108. In certain examples the ceramic layer 106 may include aluminum oxide (Al₂O₃) or alumina and in this respect may consist of or consist essentially of aluminum oxide (Al₂O₃) or alumina. In accordance with certain examples, the ceramic layer 106 may include yttria, and may consist of or consist essentially of yttrium(III) oxide (Y₂O₃). It is contemplated that the ceramic layer 106 may be deposited using an ALD technique, the ceramic layer 106 being relatively dense and/or homogenous in relation to ceramic layers of similar composition formed using other techniques, such as CVD techniques. It is also contemplated that the ceramic layer 106 may be formed using a CVD technique and remain within the scope of the present disclosure. As will be appreciated by those of skill in the art in view of the present disclosure, coating the workpiece body 102 with aluminum oxide (Al₂O₃) aluminum oxide (Al₂O₃) or alumina, or yttrium(III) oxide (Y₂O₃) in certain examples of the present disclosure, may improve interaction of the metallic workpiece with certain fluids, for example by promoting the survival by limiting recombination tendencies of certain radical specie, such as hydrogen radicals and certain halogen radicals, such as fluorine radicals by way of non-limiting example.

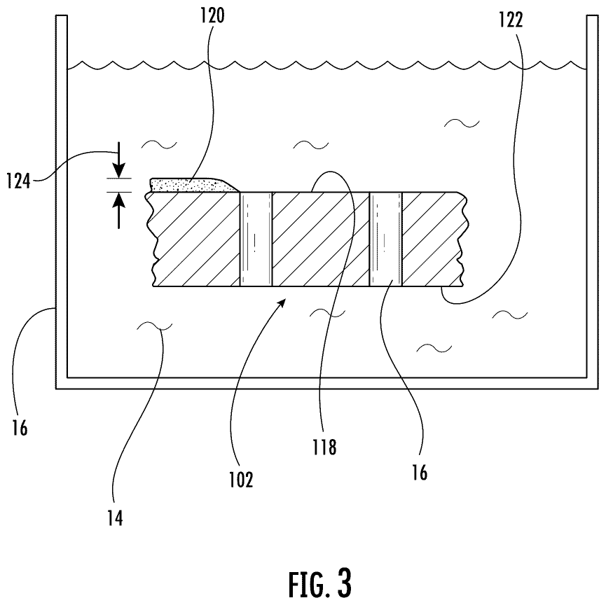

It is contemplated that the workpiece body 102 having a thickness 110, that the metallic oxide layer 104 have a thickness 112, and that the ceramic layer have a thickness 114. In certain examples of the present disclosure the thickness 110 of the workpiece body 102 may be greater than the thickness 112 of the metallic oxide layer 104. The thickness 110 of the workpiece body 102 may be greater than the thickness 114 of the ceramic layer 106. The thickness 110 of the workpiece body 102 may be greater than both the thickness 112 of the metallic oxide layer 104 and the thickness 114 of the ceramic layer 106. In certain examples the thickness 110 may between about 5 millimeters and about 20 millimeters, or between about 5 millimeters and about 15 millimeters, or even between about 5 millimeters and about 10 millimeters. As will be appreciated by those of skill in the art in view of the present disclosure, thicknesses within these ranges can promote flow stability of fluids flowing through flow apertures 116 (shown in FIG. 3) extending through the metallic article 100.

In certain examples, the thickness 112 of metallic oxide layer 104 may have a thickness that is less than the thickness 114 of the 110 of the workpiece body 102. In accordance with certain examples, the thickness 112 of the metallic oxide layer 104 may be greater than a thickness of the ceramic layer 106. For example, the thickness 112 of the metallic oxide layer 104 may be between about 10 nanometers and about 100 nanometers, or between about 10 nanometers and about 80 nanometers, or even between about 10 nanometers and about 50 nanometers. Advantageously, thicknesses within these ranges can provide beneficial adhesion (e.g., coupling) of the ceramic layer 106 to workpiece body 102 by the metallic oxide layer 104. To further advantage, such thicknesses can be formed at relatively low temperature, i.e., temperatures lower than that required to form nickel oxide from oxygen (O₂) gas, and more rapidly than required to form nickel oxide from oxygen (O₂) gas, limiting cost and time require to fabricate the metallic article 100. It is also contemplated that the thickness 112 of the metallic oxide layer 104 may be greater than the thickness 114 of the ceramic layer 106, and that thickness 112 be common for examples wherein the ceramic layer 106 includes aluminum oxide (Al₂O₃) as well as in examples wherein the ceramic layer 106 includes yttrium(III) oxide (Y₂O₃).

In certain examples the thickness 114 of the ceramic layer 106 may be greater than the thickness 112 of the metallic oxide layer 104. In accordance with certain examples, the thickness 114 of the ceramic layer 106 may be less than the thickness 110 of the workpiece body 102. It is also contemplated that the thickness 114 of the ceramic layer 106 may be greater that the thickness 112 of the metallic oxide layer 104 and less than the thickness 110 of the workpiece body 102. For example, the thickness 114 may be between 1 nanometer and 10,000 nanometers, or between about 1 nanometer and about 2,500 nanometers, or between about 100 nanometers and about 500 nanometers in examples wherein the ceramic layer 106 includes alumina as well as examples wherein the ceramic layer 106 includes yttrium(III) oxide (Y₂O₃). Examples of suitable ceramic layers include those shown and described in U.S. Patent Application Publication No. 2020/0131634 A1 to Gao et al., filed on Oct. 26, 2018, the contents of which is incorporated herein by reference in its entirety.

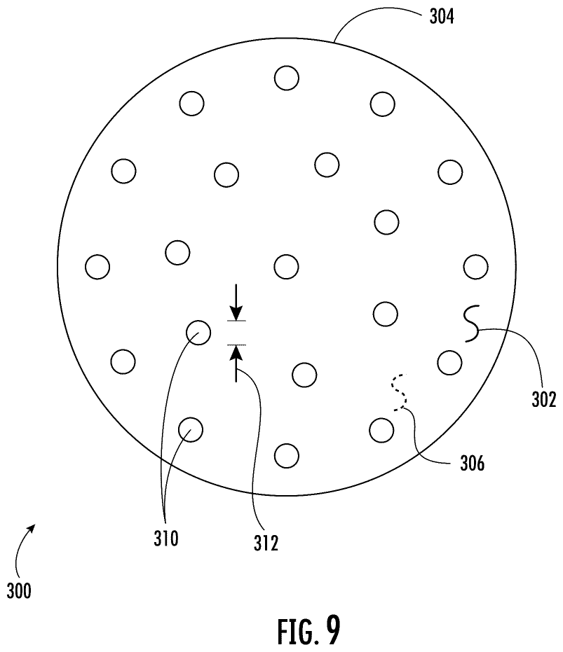

Referring to FIGS. 2-5, operations for making the metallic article 100 are shown. As shown in FIG. 2, fabrication of the metallic article 100 (shown in FIG. 1) may be accomplished by forming the workpiece body 102 from the bulk metallic material 108, for example from solid nickel (Ni) metal (nickel alloy Ni-200) or solid aluminum (Al) metal (1050 aluminum). Forming the workpiece body 102 may include defining 212 a first surface 118 of the workpiece body 102, such as by defining the first surface 118 with a generally circular periphery, e.g., a generally circular periphery 304 (shown in FIG. 9), extending about the workpiece body 102. Forming the workpiece body 102 may include defining 214 a second surface 122 separated from the first surface 118 by a thickness of the workpiece body 102, for example the thickness 110 of the workpiece body 102. Forming the workpiece body 102 may further include defining plurality of flow apertures 116 within the workpiece body 102 fluidly coupling the first surface 118 of the workpiece body 102 to the second surface 122 of the workpiece body 102. The plurality of flow apertures 116 may be formed using a subtractive manufacture technique, for example using a drilling or reaming tool 10. The plurality of flow apertures 116 may be formed coincident with one another, for example by fusing a plurality of metallic layers 12 using an additive manufacturing technique like powder bed fusion, and remain within the scope of the present disclosure.

As shown in FIG. 3, once the workpiece body 102 is formed, the workpiece body 102 may be wet cleaned. Wet cleaning may be accomplished by immersing the workpiece body 102 within a solvent and/or etchant 14 contained within a tank or wet bench 16, for example subsequent to defining the plurality of flow apertures 116. The solvent and/or etchant 14 may be operative to mobilize contaminant resident on the workpiece body 102, for example residual cutting fluid and/or cutting debris resident within one or more of the plurality of flow apertures 116, disposed on the periphery of the workpiece body 102, and/or residing on the first surface 118 and/or the second surface 122 associated with a subtractive manufacturing technique employed to form the workpiece body 102. In certain examples a native oxide may form on the workpiece body 102, for example a first metallic oxide layer 120 on the workpiece body 102. In accordance with certain examples, the first metallic oxide layer 120 may include (or consist of or consist essentially of) aluminum oxide (Al₂O₃). In such examples the first metallic oxide layer 120 may be relatively thin, the first metallic oxide layer 120 having a thickness 124 that is less than either (or both) the thickness 112 (shown in FIG. 1) and the thickness 114 (shown in FIG. 1). For example, the thickness 124 of the first metallic oxide layer 120 may be less than about 20 nanometers, or less than about 10 nanometers, or even less than about 5 nanometers and remain within the scope of the present disclosure.

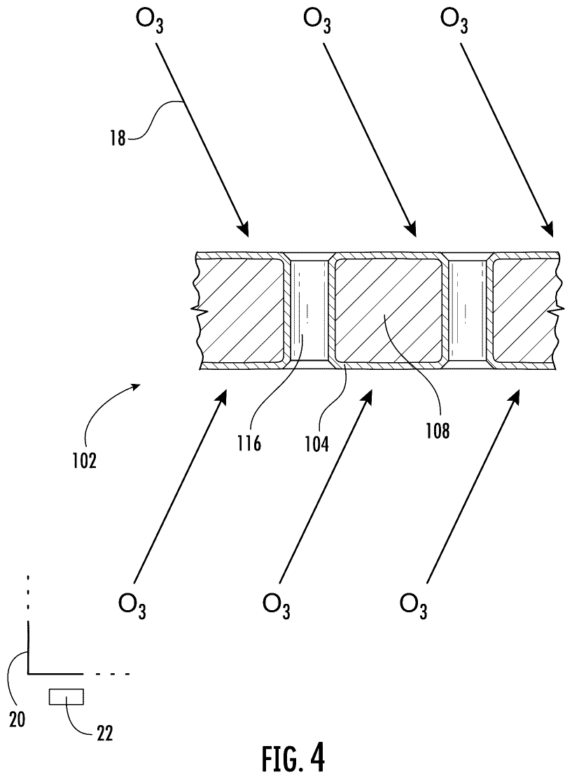

As shown in FIG. 4, once the workpiece body 102 has been formed and optionally wet cleaned, the metallic oxide layer 104 may be formed. In this respect the metallic oxide layer 104 may be conformally formed within the plurality of flow apertures 116 and conformally onto surfaces defined by the bulk metallic material 108 and bounding the plurality of flow apertures 116. Forming of the metallic oxide layer 104 may be accomplished by exposing the workpiece body 102, and more particularly the bulk metallic material 108 forming the workpiece body 102, to ozone (O₃) 18, for example to ozone (O₃) gas. In this respect it is contemplated that that the metallic oxide layer 104 be formed such that the metallic oxide layer 104 overlays the bulk metallic material 108 forming the workpiece body 102, for example in a substantially conformal encapsulation. Forming the metallic oxide layer 104 may be accomplished within an ozone chamber 20. Once supported within the ozone chamber 20, the workpiece body 102 may be heated to a predetermined ozone (O₃) treatment temperature, for example using a heater element 22. The workpiece body 102 may be heated to a temperature below that at which nickel oxide forms in the presence of oxygen (O₂) gas, for example to a predetermined ozone (O₃) treatment temperature that is between about 200 degrees Celsius and about 400 degrees Celsius, or between about 200 degrees Celsius and about 350 degrees Celsius, or between about 200 degrees Celsius and about 300 degrees Celsius, or even that is between about 200 degrees Celsius and about 250 degrees Celsius. Advantageously, temperatures within these ranges cooperate with the greater reactivity of ozone (O₃) relative to oxygen (O₂) gas, reducing time required form the metallic oxide layer 104, reducing time and cost of fabrication of the metallic article 100 (shown in FIG. 1).

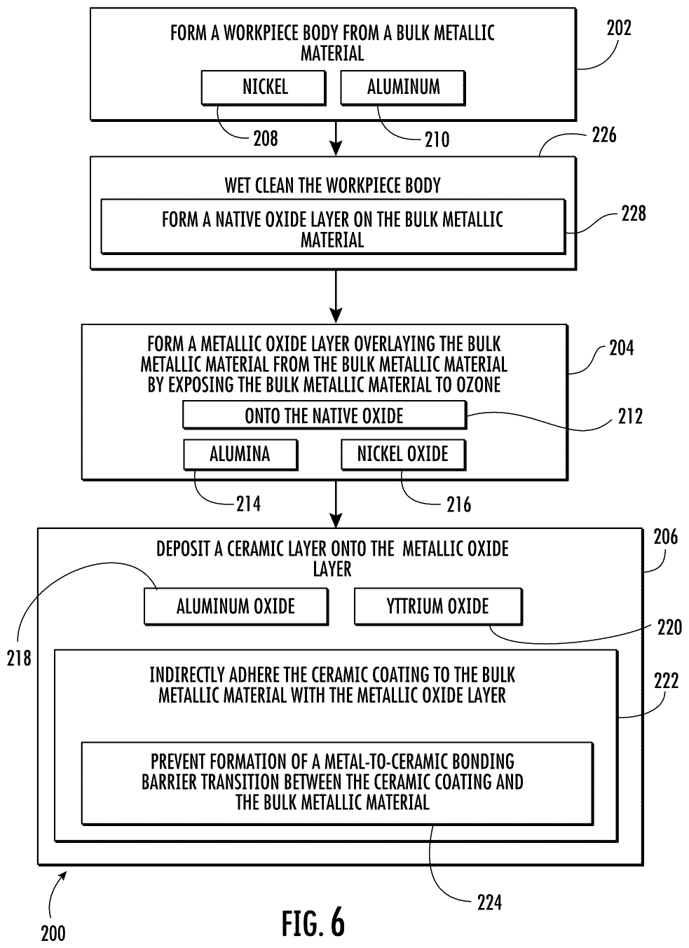

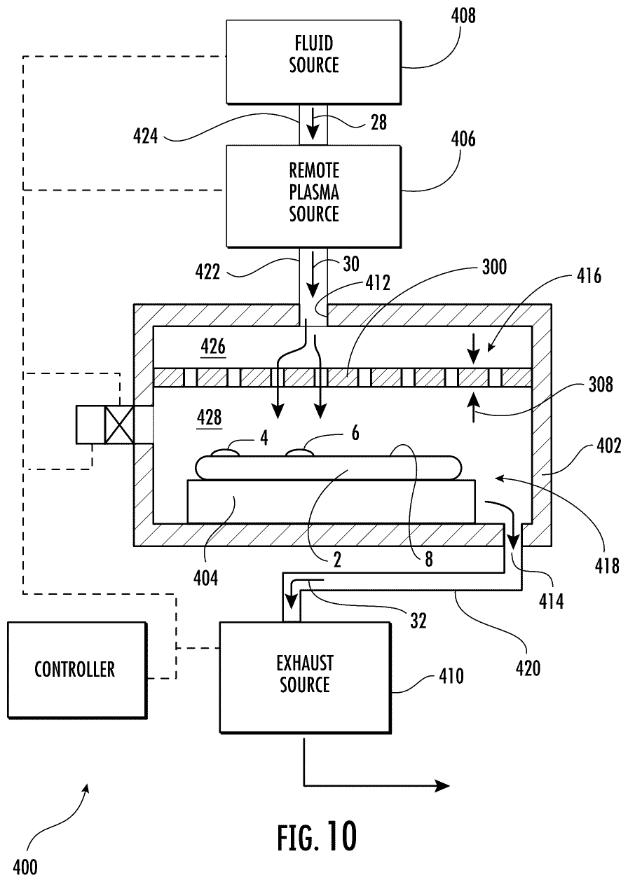

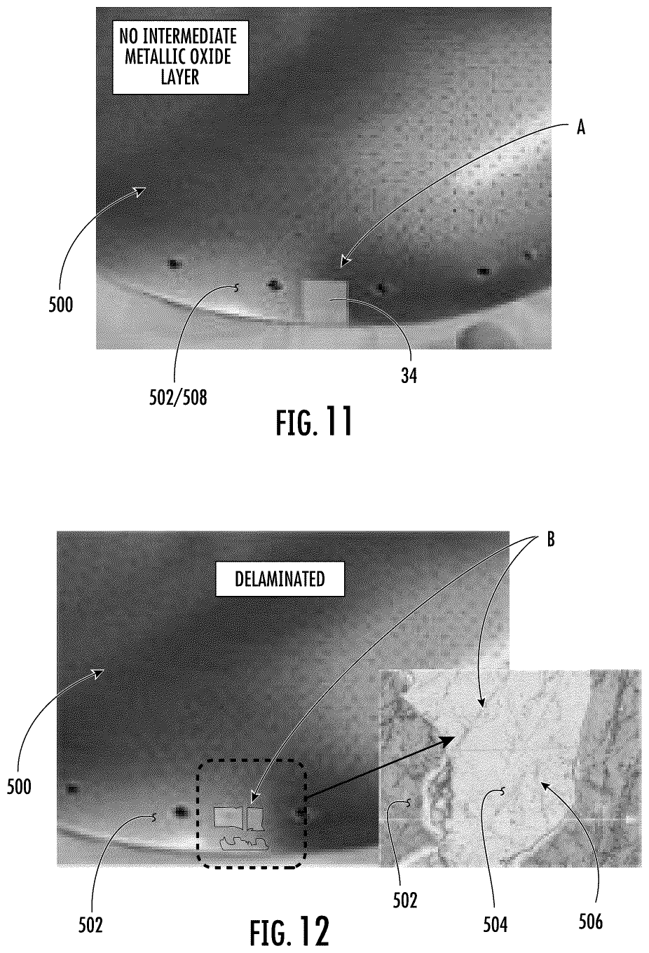

Once heated to the predetermined ozone (O₃) treatment temperature the workpiece body 102 may be exposed to ozone (O₃), e.g., ozone (O₃) gas, for a predetermined ozone (O₃) treatment exposure interval. In this respect it is contemplated that the predetermined ozone (O₃) treatment exposure interval may be between about 15 minutes and about 5 hours, or between about 15 minutes and about 4 hours, or between about 15 minutes and about 3 hours, or even between about 15 minutes and about 2 hours. Advantageously, predetermined ozone (O₃) treatment temperatures and predetermined ozone (O₃) exposure intervals within these ranges can form the metallic oxide layer 104 with thickness sufficient enable greater adherence between the ceramic layer 106 (shown in FIG. 1) and the bulk metallic material 108 without forming a metal-to-ceramic bonding barrier transition 508 (shown in FIG. 11) between the bulk metallic material 108 and the ceramic layer 106, limiting (or eliminating) risk that the ceramic layer 106 separate (e.g., delaminate) from the workpiece body. As will be appreciated by those of skill in the art in view of the present disclosure, this can limit risk that the metallic article 100 (shown in FIG. 1) generate particles during service. As will also be appreciated by those of skill in the art in view of the present disclosure, it can also limit (or eliminate) risk of damage to the ceramic layer 106 during installation and/or removal of the metallic article 100 from the end item, e.g., a semiconductor processing system 400 (shown in FIG. 10), incorporating a showerhead metallic article 300 (shown in FIG. 9) made in accordance with a method 200 (shown in FIG. 6) of making metallic article as shown and described herein.

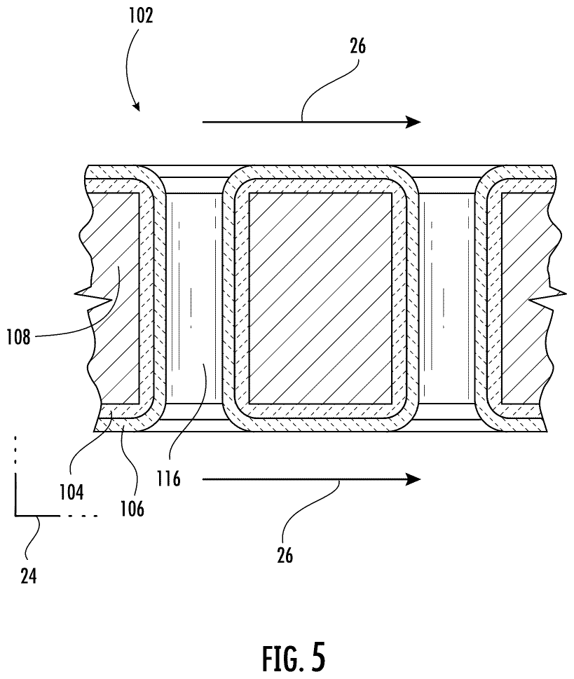

As shown in FIG. 5, the ceramic layer 106 may be deposited onto the metallic oxide layer 104 subsequent to forming the metallic oxide layer 104, for example conformally over the metallic oxide layer 104. For example, the ceramic layer 106 may be conformally deposited over the metallic oxide layer 104 over surfaces bounding the plurality of flow apertures 116. In certain examples the ceramic layer 106 may be deposited using CVD technique. In accordance with certain examples, the ceramic layer 106 may be deposited using an ALD technique. It is contemplated that the ceramic layer 106 may include aluminum oxide (Al₂O₃), such as aluminum oxide (Al₂O₃) deposited using a CVD or ALD technique. It is also contemplated that ceramic layer 106 may include yttrium(III) oxide (Y₂O₃), such yttrium(III) oxide (Y₂O₃) deposited using a CVD or an ALD technique, such as by supporting the workpiece body 102 within an CVD or ALD deposition chamber 24 and exposing the workpiece body to a CVD precursor or an ALD reactant 26. Examples of suitable deposition techniques include those shown and described in U.S. Patent Application Publication No. 2020/0131634 A1 to Goa et al, filed on Oct. 26, 2018, which, as has been stated above, is incorporated herein by reference in its entirety.

Referring to FIGS. 6-8, a method 200 of making a metallic article, e.g., the metallic article 100 (shown in FIG. 1), is shown. As shown in FIG. 6, the method 200 includes forming a workpiece body from a bulk metallic material, e.g., the workpiece body 102 (shown in FIG. 1) from the bulk metallic material 108 (shown in FIG. 1), as shown with box 202. The method 200 also includes forming a metallic oxide layer overlaying the bulk metallic material, e.g., the metallic oxide layer 104 (shown in FIG. 1), by exposing the bulk metallic material to ozone (O₃), such as ozone (O₃) gas, as shown with box 204. The method 200 further includes depositing a ceramic layer onto the metallic oxide layer overlaying the bulk metallic material, e.g., the ceramic layer 106 (shown in FIG. 1), as shown with box 206.

Forming 202 the workpiece body may include forming the workpiece body from nickel (Ni), as shown with box 208. For example, the bulk metallic material may be solid nickel (Ni) metal, the bulk metallic material consisting of or consisting essentially of nickel in such examples, as also shown with box 208. In certain examples, the bulk metallic material may be a nickel-containing alloy, such as a stainless steel material, as further shown with box 208. Forming 202 the workpiece body may include forming the workpiece body from aluminum (Al), as shown with box 210. In this respect the bulk metallic material may be solid aluminum (Al) metal, the bulk metallic material consisting of or consisting essentially of aluminum (Al) in such examples, as also shown with box 210. In further respect, the bulk metallic material may be an aluminum-containing alloy, such as 6064 aluminum alloy, as further shown with box 210.

Forming 204 the metallic oxide layer may include forming the metallic oxide layer onto a native oxide layer overlaying the bulk metallic material. In such examples native oxide layer may be a first metallic oxide layer and the metallic oxide layer formed by exposing the workpiece body to ozone (O₃) may be a second metallic oxide layer overlaying the first metallic oxide layer and separated from the bulk metallic material by the first metallic oxide layer, as shown with box 212. Forming 204 the metallic oxide layer by exposing the bulk metallic material to ozone (O₃) may include forming an alumina or aluminum oxide (Al₂O₃) layer onto the bulk metallic material from the bulk metallic material, as shown with box 214. Forming the metallic oxide layer by exposing the bulk metallic material to ozone (O₃) may include forming a nickel oxide onto the bulk metallic material from the bulk metallic material, as shown with box 214. In this respect the metallic oxide layer may include (or consist of or consist essential of) nickel oxide, e.g., basic nickel(II) oxide (NiO), as also shown with box 216. It is also contemplated that the metallic oxide layer may include (or consist of or consist essentially of) a non-basic nickel oxide, e.g., nickel(III) oxide (Ni₂O₃), and remain within the scope of the present disclosure.

Depositing 206 the ceramic layer onto the metallic oxide layer may include depositing an aluminum oxide (Al₂O₃) onto the metallic oxide layer, as shown with box 218. The aluminum oxide (Al₂O₃) layer may consist of or consist essentially of aluminum oxide (Al₂O₃), as also shown with box 218. Depositing 206 the ceramic layer onto the metallic oxide layer may include depositing yttrium(III) oxide (Y₂O₃) onto the metallic oxide layer, as shown with box 220. The yttrium(III) oxide (Y₂O₃) layer may consist of or consist essentially of yttrium(III) oxide (Y₂O₃), as also show with box 220. It is contemplated that the ceramic layer be indirectly adhered to the bulk metallic material by the metallic oxide layer, as shown with box 222. It is also contemplated that metallic oxide layer prevent formation of a metal-to-ceramic bonding barrier between the ceramic coating the bulk metallic material, for example such that can otherwise exist between nickel (Ni) metal and yttrium(III) oxide (Y₂O₃), limiting (or eliminating) the tendency of such bonding barriers to limit adhesion of the ceramic layer to the bulk metallic material, as shown with box 224. Advantageously, and as demonstrated by adherence testing a metallic article not having the metallic oxide layer (shown in FIGS. 11 and 12) and a metallic article including a metallic oxide layer formed by exposure of a bulk metallic material to ozone (O₃), indirectly adhering the ceramic coating to the bulk material increases force required to delaminate the ceramic coating from the metallic article made using the method 200 relative to the metallic article made without ozone (O₃) treatment and not having the resultant metallic oxide layer.

Optionally, the workpiece body may be wet cleaned, for example subsequent to forming 202 the workpiece body and prior to forming 204 the metallic oxide onto the workpiece body, as shown with box 226. In this respect the workpiece body may be immersed within a cleaning solvent or etchant contained within a tank or wet bench, e.g., the cleaning solvent or etchant 14 (shown in FIG. 3) contained within the tank or wet bench 16 (shown in FIG. 3), as also shows with box 226. In further respect, the wet cleaning the workpiece body may include degreasing and/or removing chips or cutting debris from the workpiece body, such as using a degreaser and/or an ultrasonic or megasonic cleaning technique, as further shown with box 226.

In certain examples, wet cleaning the workpiece body may include forming a native oxide layer onto the bulk metallic material, e.g., the native oxide layer forming the first metallic oxide layer 120 (shown in FIG. 3), as shown with box 228. For example, the bulk metallic material forming the workpiece body may include exposed aluminum (Al) metal, and wet cleaning may form a first metallic oxide layer including aluminum oxide (Al₂O₃) onto the exposed aluminum (Al) metal. In such examples forming 204 the metallic oxide layer may include thickening the native oxide layer, the metallic oxide layer 104 being a second metallic oxide layer in such examples, advantageously increasing adhesion of the ceramic layer subsequent deposited onto the workpiece body to a level greater than otherwise possible in techniques adhering the ceramic layer using native oxide. In this respect it is contemplated that the native oxide layer may be a first metallic oxide layer of aluminum oxide (Al₂O₃), that the metallic oxide layer formed by exposure to ozone (O₃) may be a second metallic oxide layer of aluminum oxide (Al₂O₃), and that the second metallic oxide have a thickness greater than that of the first metallic oxide layer. For example, the first metallic oxide layer may have a thickness that is between about 2 nanometers and about 10 nanometers, and that second metallic oxide layer may have a thickness that is between about 25 nanometers and about 7 nanometers.

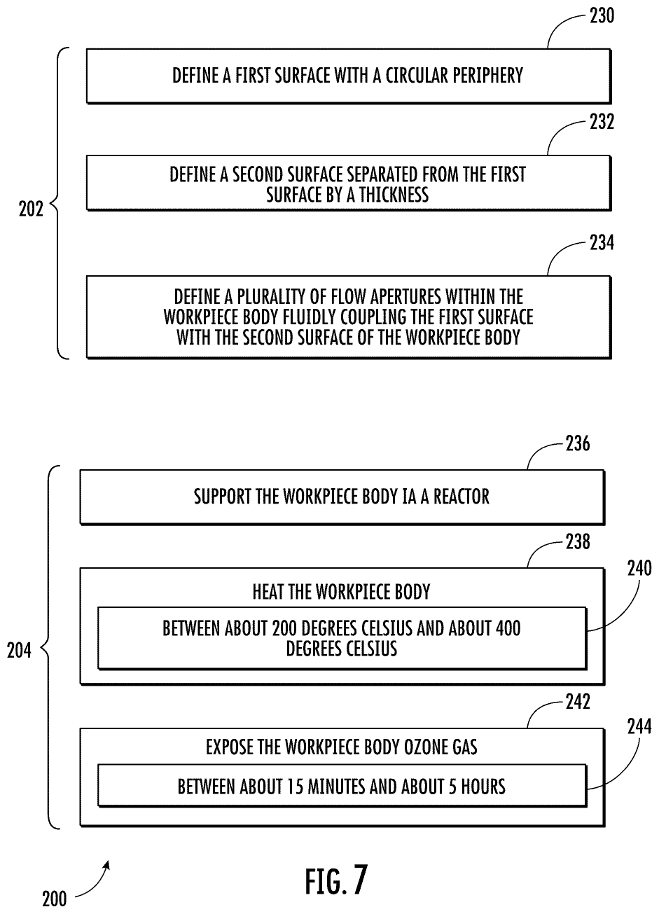

As shown in FIG. 7, forming 202 the workpiece body may further include defining a first surface with a generally circular periphery in certain examples of the present disclosure, e.g., a first surface 302 (shown in FIG. 9) having a generally circular periphery 304 (shown in FIG. 9), as shown with box 230. Forming 202 the workpiece body may also include forming a second surface having the generally circular periphery, e.g., a second surface 306 (shown in FIG. 9), as shown with box 232. Forming 202 the workpiece body may further include defining a plurality of flow apertures within the workpiece body and fluidly coupling the first surface to the second surface, e.g., the plurality of flow apertures 310 (shown in FIG. 9), as shown with box 234. In these respects the metallic workpiece may be formed (and thereby configured and adapted) as a showerhead for a semiconductor processing system, e.g., a showerhead metallic article 300 (shown in FIG. 9) for a semiconductor processing system 400 (shown in FIG. 10), such as a semiconductor processing system having a downflow-type architecture, as shown with bracket 202. In such examples the ozone (O₃) may be forced through the plurality of flow apertures to form the metallic oxide layer conformally and to a substantially uniform thickness within the plurality of flow apertures, advantageously limiting (or eliminating) erosion of the ceramic layer subsequently deposited within the plurality of flow apertures and adhered to the bulk metallic material by the metallic oxide layer formed within the plurality of flow apertures, as also shown with bracket 202.

In accordance with certain examples of the present disclosure, forming 204 the metallic oxide layer may include supporting the metallic workpiece in a reactor, e.g., the ozone chamber 20 (shown in FIG. 4), as shown with box 236. Therein the workpiece body may be heated to a predetermined metallic oxide forming temperature, as shown with box 238. Heating 238 may be accomplished in such examples using a heater element in thermal communication with the reactor, e.g., the heater element 22 (shown in FIG. 4), as also shown with box 238. Heating 238 the workpiece body may include heating the workpiece body to a temperature less than that required to oxidize nickel (Ni) metal in an oxygen (O₂) gas-containing atmosphere, as shown with box 240. For example, the workpiece body may be heated to a predetermined metallic oxide forming temperature that is between about 200 degrees Celsius and about 400 degrees Celsius, such as between about 200 degrees Celsius and about 350 degrees Celsius, or between about 200 degrees Celsius and about 300 degrees Celsius, or even that is between about 200 degrees Celsius and about 250 degrees Celsius, as also shown with box 240. In further examples, heating may remove residual organic materials (e.g., oils) resident on surfaces of the workpiece body, such as in examples where wet cleaning is not employed or when wet cleaning excludes degreasing solvent, limiting generation of potentially hazardous material during fabrication of the metallic article.

It is contemplated that forming 204 the metallic oxide layer may include maintaining the workpiece body at the predetermined metallic oxide forming temperature for a predetermined ozone (O₃) exposure interval, as shown with box 242. In this respect the predetermined ozone (O₃) exposure interval may be between about 15 minutes and 5 hours, as shown with box 244. For example, the workpiece body may be maintained at the predetermined metallic oxide forming temperature for a predetermined ozone (O₃) exposure interval that is between about 15 minutes and about 4 hours, or is between about 15 minutes and about 3 hours, or between about 15 minutes and about 2 hours, or even between about 15 minutes and 1 hour, as also shown with box 244. Advantageously, predetermined metallic oxide forming temperatures and predetermined ozone (O₃) exposure intervals can impart thickness into the metallic oxide layer sufficient to increase adhesion of the subsequently deposited ceramic layer more quickly than exposure to oxygen (O₂) gas, simplifying fabrication of the metallic article by exploiting the relatively high reactivity of ozone (O₃) relative to oxygen (O₂) gas to certain bulk metallic materials, such as nickel (Ni) metal and aluminum (Al) metal. It is also contemplated that forming 204 the metallic oxide layer onto the bulk metallic material forming the workpiece body may cure porosity and/or surface roughness within the plurality of flow apertures otherwise associated with forming of the workpiece body using an additive manufacturing technique, as further shown with bracket 204. As will be appreciated by those of skill in the art in view of the present disclosure, this can improve the flow characteristics provided by the metallic workpiece when employed as a showerhead, for example by promoting laminar flow of fluids through the plurality of flow apertures fluidly coupling the first surface to the second surface of the metallic workpiece.

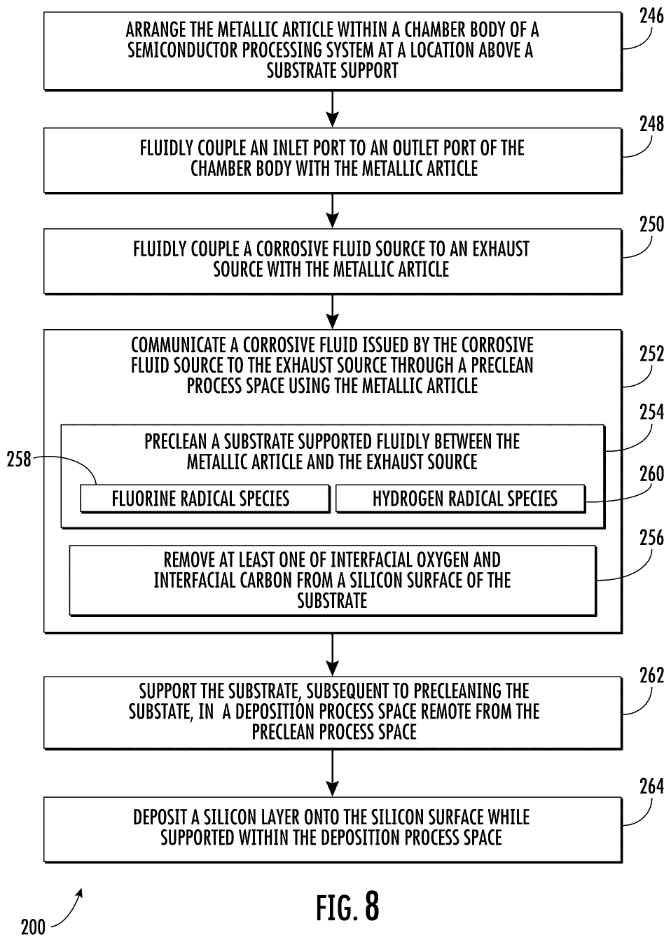

As shown in FIG. 8, the method 200 may further include arranging the metallic article within a chamber body of a semiconductor processing system, e.g., within the chamber body 402 (shown in FIG. 10) of the semiconductor processing system 400 (shown in FIG. 10), as shown with box 246. In this respect the metallic article may be formed as a showerhead and thereby fluidly couple an inlet port of the chamber body to an outlet port of the chamber body, e.g., the inlet port 314 (shown in FIG. 10) to the outlet port 316 (shown in FIG. 10), as shown with box 248. In further respect, the metallic article may fluidly couple a corrosive fluid source to an exhaust source, e.g., a fluid source 408 (shown in FIG. 10) to an exhaust source 410 (shown in

FIG. 10), as shown with box 250. So arranged, a corrosive fluid issued by the corrosive fluid source may be communicated by the metallic article to the exhaust source through a preclean space defined within the chamber body, e.g., a corrosive fluid 28 (shown in FIG. 10) communicated through a preclean process space 428 (shown in FIG. 10), as shown with box 252. Therein the corrosive fluid may preclean a substrate supported within the preclean space and remove one or more of interfacial oxygen and/or interfacial carbon from a substrate having a silicon surface portion, e.g., remove interfacial carbon 6 (shown in FIG. 10) and/or interfacial oxygen 4 (shown in FIG. 10) from a substrate 2 (shown in FIG. 10) supported within the preclean space, as shown with box 254 and with box 256.

In certain examples, the corrosive fluid may include a fluorine radical species, as shown with box 258. In accordance with certain examples, the corrosive fluid may include a hydrogen radical species, as shown with box 260. It is contemplated that a material layer may thereafter be deposited onto the substrate, for example by transferring the substrate from the preclean process space to a deposition process space remote from the preclean process space, as shown with box 262. Therein the material layer, e.g., an epitaxial silicon-containing material layer, may be deposited onto the silicon surface, for example using a CVD technique, as shown with box 264. As will be appreciated by those of skill in the art in view of the present disclosure, precleaning the substrate may improve quality of the material layer deposited onto the substrate by limiting (or eliminating) interfacial oxygen and/or interfacial carbon otherwise potentially resident on the substrate surface. As will also be appreciated by those of skill in art, the relatively high adhesion provided by the metallic oxide layer formed by exposing the workpiece body to ozone (O₃) may increase the expected service life of the metallic article, for example by delaying (or preventing) contamination generation associated with potential erosion and/or delamination of the ceramic layer by fluid traversing the metallic article.

Referring to FIGS. 9 and 10, a showerhead metallic article 300 and a semiconductor processing system 400 including the showerhead metallic article 300 are shown. As shown in FIG. 9, the showerhead metallic article 300 is similar to the metallic article 100 (shown in FIG. 1) and additionally has a first surface 302 defining a generally circular periphery 304. The showerhead metallic article 300 also has a second surface 306 defining the generally circular periphery 304 and a thickness 308 (shown in FIG. 10) separating the second surface 306 from the first surface 302. It is contemplated that the showerhead metallic article 300 further define therethrough a plurality of flow apertures 310. In this respect it is contemplated that the plurality of flow apertures 310 extend through the thickness 308 of the showerhead metallic article 300 and fluidly coupling the first surface 302 to the second surface 306 to communicate fluid therethrough. In further respect, the plurality of flow apertures 310 may have an effective flow area width 312. The effective flow area width 312 may be between about 0.25 millimeters and about 4 millimeters, for example between about 0.25 millimeters and about 3 millimeters, or between about 0.25 millimeters and about 2 millimeters, or even between about 0.25 millimeters and about 1 millimeter.

It is contemplated that the showerhead metallic article 300 be configured as a showerhead for a semiconductor processing system, e.g., the semiconductor processing system 400, and in this respect the plurality of flow apertures 310 may be sized and distributed according the process performed within the semiconductor processing system. In further respect, either (or both) the metallic oxide layer 104 (shown in FIG. 1) and the ceramic layer 106 (shown in FIG. 1) may be conformally disposed within the plurality of flow apertures 310 and sized (e.g., in terms of respective thickness) to limit (or eliminate) delamination as well as encourage laminar fluid flow within the plurality of flow apertures 310. Moreover, in examples wherein the workpiece body 102 (shown in FIG. 1) is formed using an additive manufacturing process, either (or both) the metallic oxide layer 104 and the ceramic layer 106 may operate as countermeasures to otherwise potentially deleterious properties imparted to the showerhead metallic article 300. For example, either (or both) the metallic oxide layer 104 and the ceramic layer 106 may operate as countermeasures to porosity within the bulk metallic material 108 (shown in FIG. 1) (e.g., by sealing) on the workpiece body generally. Either (or both) the metallic oxide layer 104 and the ceramic layer 106 may operate and/or surface roughness within the plurality of flow apertures 310 associated with certain additive manufacturing techniques, such as powder bed fusion, by smoothing fluid-contacting surfaces within the plurality of flow apertures 310. As will be appreciated by those of skill in the art in view of the present disclosure, this can simplify fabrication of the showerhead metallic workpiece, for example by limiting (or eliminating) the need to smooth interior surfaces of the plurality of flow passages, for example using a hydro honing technique, controlling the thickness 112 (shown in FIG. 1) of the metallic oxide layer 104 formed within the plurality of flow apertures 310.

As shown in FIG. 10, the semiconductor processing system 400 may include a chamber body 402, a substrate support 404, a remote plasma unit 406, a fluid source 408, and an exhaust source 410. The chamber body 402 may have an inlet port 412, an outlet port 414, and generally define a downflow-type chamber architecture 416. The substrate support 404 may be arranged within an interior 418 of the chamber body 402. The substrate support 404 may further be configured to seat thereon a substrate 2 during precleaning of the substrate 2, for example during removal of one or more of interfacial oxygen 4 and/or interfacial carbon 6 from a silicon surface portion 8 of the substrate 2 prior to deposition of an epitaxial silicon material layer onto the substrate 2 in a remote deposition process module on a cluster-type platform. The exhaust source 410 may be coupled to the outlet port 414 of the chamber body 402, for example through an exhaust conduit 420, and be configured to evacuate the interior 418 of the chamber body 402 using one or more vacuum pump. In this respect the exhaust source 410 may be configured to remove residual radical species and/or reaction products 32 from within the interior 418 of the chamber body 402 during precleaning of the substrate 2.

The remote plasma unit 406 may be coupled to the inlet port 412 of the chamber body 402 by a supply conduit 422 and configured to communicate a radical species 30 to the interior 418 of the chamber body 402, for example to preclean the substrate 2. The remote plasma unit 406 may further be coupled to the fluid source 408 by a source conduit 424 to receive the corrosive fluid 28 from the fluid source 408 and generate the radical species 30 therefrom. The fluid source 408 may in turn be configured to provide the corrosive fluid 28 to the remote plasma unit 406. In certain examples, the corrosive fluid 28 may include a halogen, such as fluorine (e.g., NF₃, CF₄, SF₆, or C₂F₆) or chlorine (e.g., chlorine Cl₂ gas), and the remote plasma unit 406 may be configured to generate halogen radicals from the corrosive fluid 28, such as fluorine radicals and/or chlorine radicals. In accordance with certain examples, the corrosive fluid 28 may include hydrogen, for example hydrogen (H₂) gas, and the remote plasma unit 406 in turn configured to generate hydrogen radicals from the corrosive fluid 28. As will be appreciated by those of skill in the art in view of the present disclosure, other make-up fluids and/or radical species may be employed and remain within the scope of the present disclosure. Examples of suitable remote plasma units include Paragon® remote plasma sources, available from MKS Instruments, Inc. of Andover, Massachusetts.

The showerhead metallic article 300 may be fixed within the interior 418 of the chamber body 402. The showerhead metallic article 300 may further separate the interior 418 of the chamber body 402 into a supply plenum 426 and a preclean process space 428, and additionally fluidly couple the supply plenum 426 to the preclean process space 428 via the plurality of flow apertures 310. As will be appreciated by those of skill in the art in view of the present disclosure, the ceramic layer 106 (shown in FIG. 1) included in the showerhead metallic article 300 may promote survival radical species received from the remote plasma unit 406, for example by reducing tendency of hydrogen radicals to recombine. As will also be appreciated by those of skill in the art in view of the present disclosure, the metallic oxide layer 104 (shown in FIG. 1) coupling the ceramic layer 106 to the bulk metallic material 108 (shown in FIG. 1) forming the workpiece body 102 (shown in FIG. 1) of the showerhead metallic article 300 may limit (or eliminate) tendency of the ceramic layer 106 to delaminate and/or erode during communication of fluid through the plurality of flow apertures 310 due to the aforementioned relatively high adhesion of the ceramic layer 106 to the bulk metallic material 108 provided by the metallic oxide layer 104 relative to showerhead metallic articles of similar composition not receiving ozone (O₃) treatment prior to deposition of ceramic layers, prolonging the expected service life of the showerhead metallic article 300 and limiting cost of ownership of the semiconductor processing system 400.

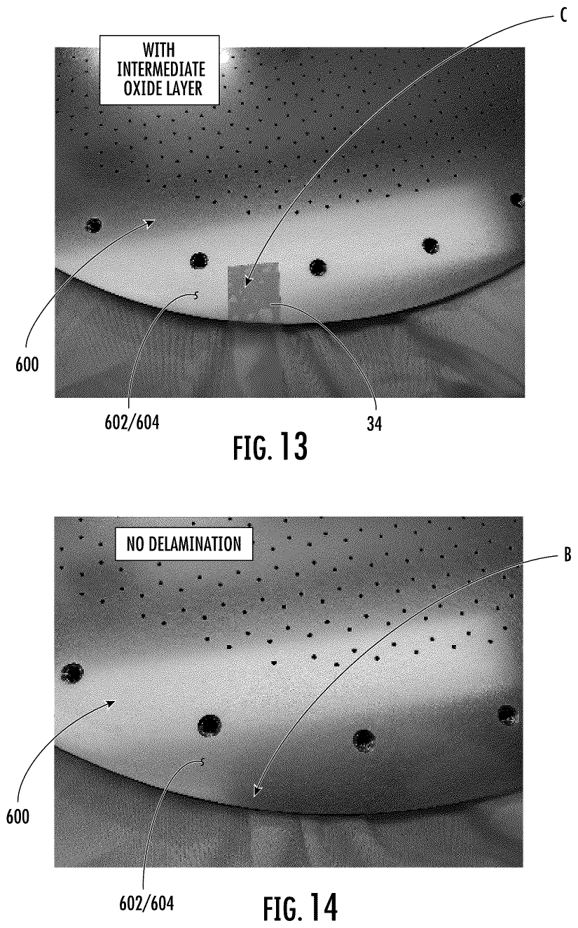

Referring to FIGS. 11-14, a metallic article 500 having a ceramic layer 502 and a metallic article 600 having both a metallic oxide layer 602 and a ceramic layer 604 in accordance with the present disclosure are shown undergoing ceramic layer adhesion tests. As shown at A in FIG. 11 and B in FIG. 12, application of an adhesive member 34 (shown in FIG. 11) and subsequent removal of the adhesive member 34 removes a portion of the ceramic layer 502, exposing a surface portion surface 504 of underlying bulk metal material 506 forming the metallic article 500. In contrast, and as shown at C in FIG. 13 and D in FIG. 14, application and subsequent removal of a substantially identical (e.g., in terms of adhesion) adhesive member 34 (shown in FIG. 13) removes substantially none of the ceramic layer 604, the metallic article 600 remaining serviceable notwithstanding the trauma to the ceramic layer 604 associated with the removal of the adhesive member 34. As will be appreciated by those of skill in the art in view of the present disclosure, the metallic article 600 is more likely to survive manipulation and handling during installation and/or servicing that the metallic article in addition to providing the aforementioned benefits and advantages.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A method of making a metallic article, comprising:
forming a workpiece body from a bulk metallic material, wherein the bulk metallic material includes one of aluminum and nickel;
forming a metallic oxide layer overlaying the bulk metallic material from the bulk metallic material by exposing the bulk metallic material to ozone (O₃); and
depositing a ceramic layer onto the metallic oxide layer.

2. The method of claim 1, wherein forming the workpiece body comprises:
defining a first surface with a circular periphery;
defining a second surface separated from the first surface by a thickness; and
defining a plurality of flow apertures within the workpiece body fluidly coupling the first surface with the second surface of the workpiece body.

3. The method of claim 1, wherein forming the metallic oxide layer comprises:
supporting the workpiece body in an ozone chamber;
heating the workpiece body to between about 200 degrees Celsius and about 400 degrees Celsius, or between about 200 degrees Celsius and about 350 degrees Celsius, or between about 200 degrees Celsius and about 300 degrees Celsius, or between about 200 degrees Celsius and about 250 degrees Celsius; and
exposing the workpiece body to ozone (O₃) gas for between about 15 minutes and about 5 hours, or between about 15 minutes and about 4 hours, or between about 15 minutes and about 3 hours, or between about 15 minutes and about 2 hours.

4. The method of claim 1, further comprising wet cleaning the workpiece body prior to forming the metallic oxide layer.

5. The method of claim 4, wherein substantially none of the metallic oxide layer is formed during the wet cleaning.

6. The method of claim 4, wherein the metallic oxide layer is a second metallic oxide layer, and further comprising forming a first metallic oxide layer on the workpiece body during the wet cleaning, whereby the second metallic oxide layer overlays the first metallic oxide layer following the exposing the bulk metallic material to the ozone (O₃).

7. The method of claim 1, wherein depositing the ceramic layer comprises depositing aluminum oxide (Al₂O₃) or yttrium(III) oxide (Y₂O₃) onto the metallic oxide layer.

8. The method of claim 1, indirectly adhering the ceramic layer to the bulk metallic material with the metallic oxide layer, whereby exposing the bulk metallic material to the ozone (O₃) prevents forming a metal-to-ceramic bonding barrier transition between the bulk metallic material and the ceramic layer operable to limit adhesion of the ceramic layer to the bulk metallic material.

9. The method of claim 1, further comprising, subsequent to depositing the ceramic layer onto the metallic oxide layer overlaying the bulk metallic material, arranging the metallic article within a chamber body of a semiconductor processing system above a substrate support such that the metallic article fluidly couples an inlet port to an outlet port of the chamber body.

10. The method of claim 1, further comprising:
fluidly coupling a fluid source to an exhaust source with the metallic article;
communicating a corrosive fluid issued by the fluid source to the exhaust source through a preclean process space the metallic article;
precleaning a substrate supported fluidly between the metallic article and the exhaust source, wherein the corrosive fluid includes a radical species, and whereby at least one of interfacial oxygen and interfacial carbon are removed a silicon surface of the substrate;
supporting the substrate, subsequent to precleaning the substrate, in a deposition process space remote from the preclean process space; and
depositing a silicon-containing material layer onto the silicon surface while supported within the deposition process space.

11. A showerhead metallic article made using the method of claim 1.

12. A metallic article, comprising:
a workpiece body formed from a bulk metallic material;
a metallic oxide layer overlaying the bulk metallic material; and
a ceramic layer overlaying the metallic oxide layer, wherein the metallic oxide layer is an oxide formed from the bulk metallic material forming the workpiece body.

13. The metallic article of claim 12, wherein the bulk metallic material includes one of aluminum and nickel.

14. The metallic article of claim 12, wherein the metallic oxide layer is aluminum oxide (Al₂O₃) or nickel oxide (NiO).

15. The metallic article of claim 12, wherein the metallic oxide layer has a thickness that is between about 10 nanometers and about 100 nanometers, or is between about 20 nanometers and about 80 nanometers, or is between about 20 nanometers and about 50 nanometers.

16. The metallic article of claim 12, wherein the ceramic layer includes at least one of alumina, aluminum oxide (Al₂O₃) and yttrium(III) oxide (Y₂O₃).

17. The metallic article of claim 12, wherein metallic workpiece is configured to communicate a corrosive fluid received at first surface to a second surface through a thickness of the workpiece body formed by the bulk metallic material.

18. The metallic article of claim 12, wherein the workpiece body defines a showerhead metallic article for a semiconductor processing system.

19. The metallic article of claim 12, wherein the workpiece body has:
a first surface with a circular periphery;
a second surface separated from the first surface by a thickness; and
a plurality of flow apertures fluidly coupling the first surface with the second surface of the workpiece body, wherein the metallic oxide layer extends continuously and without interruption along interior surfaces of the plurality of flow apertures.

20. The metallic article of claim 19, wherein the plurality of flow apertures have an effective flow area width that is between about 0.25 millimeters and about 4 millimeters, or is between about 0.25 millimeters and about 3 millimeters, or is between about 0.25 millimeters and about 2 millimeters, or is between about 0.25 millimeters and about 1 millimeter.

21. A semiconductor processing system, comprising:
a chamber body with an inlet port and an outlet port;
a substrate support arranged within an interior of the chamber body;
a metallic article as recited in claim 12 seated in the interior of the chamber body and fluidly coupling the inlet port to the outlet port;
a corrosive fluid source including a corrosive fluid coupled to the inlet port; and
an exhaust source coupled to the outlet port.
